(19) United States
(12) Patent Application Publication
(10) Pub. No.: US 2009/0323281 A1
(43) Pub. Date: Dec. 31, 2009

(54) CONTROLLING AN AIRFLOW PASSING INTO AN ELECTRONIC COMPONENT CABINET

(75) Inventors: Dean F. Herring, Youngsville, NC (US); Robert A. Myers, Cary, NC (US); Jeff D. Thomas, Raleigh, NC (US)

Correspondence Address: CANTOR COLBURN LLP - IBM RESEARCH TRIANGLE PARK, 20 Church Street, 22nd Floor, Hartford, CT, 06103, US

(73) Assignee: International Business Machines Corporation, Armonk, NY (US)

(21) Appl. No.: 12/164,725

(22) Filed: Jun. 30, 2008

(51) Int. Cl. H05K 7/20

(52) U.S. Cl. 361/692

(57) ABSTRACT

Controlling an airflow passing into an electronic component cabinet includes passing an airflow into the electronic component cabinet through a first passage having a first filter, sensing a parameter of the airflow passing through the first passage, detecting a change in the parameter of the first airflow associated with a flow restriction at the first filter, and shifting a first flap from a first position allowing the airflow to pass unrestricted through the first passage, to a second position, wherein the first flap creates a flow restriction for the airflow passing though the first passage, and triggers an actuation mechanism based on the change in parameter of the first airflow. Controlling the airflow further includes opening a second flap that exposes a second passage having a second filter based on the triggering of the switch, and passing an airflow into the electronic component cabinet through the second passage.

### BACKGROUND

This invention relates to the art of electronic component cabinets and, more particularly, to a method of controlling an airflow passing into an electronic component cabinet.

Conventional electronic component cabinets include various vents that provide passage for airflow. In many cases, the vents are provided with a filter that traps and prevents duct particles carried by the airflow from entering the cabinet. Over time, the filter becomes clogged with dust particles restricting airflow into the cabinet.

### SUMMARY

Exemplary embodiments of the invention include controlling an airflow passing into an electronic component cabinet by passing the airflow into the electronic component cabinet through a first passage having a first filter, sensing a parameter of the airflow passing through the first passage, detecting a change in the parameter of the first airflow associated with a flow restriction at the first filter, positioning a first flap across the first passage based on the change in parameter of the first airflow. The first flap triggers a switch upon being closed. The method further includes opening a second flap that exposes a second passage having a second filter based on the triggering of the switch, and passing an airflow into the electronic component cabinet through the second passage.

Additional features and advantages are realized through the techniques of exemplary embodiments of the present invention. Other embodiments and aspects of the invention are described in detail herein and are considered a part of the claimed invention. For a better understanding of the invention with advantages and features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates an electronic component cabinet having an air vent having first and second airflow passages operated in accordance with an exemplary embodiment of the invention;

FIG. 2 is a cross sectional side view of the air vent of FIG. 1 illustrating an airflow through the first airflow passage;

FIG. 3 is a cross sectional side view of the air vent of FIG. 1 illustrating an airflow through the second airflow passage after the first airflow passage is closed; and

FIG. 4 is a flow chart illustrating a method of controlling an airflow passing into the electronic component cabinet through the air vent of FIG. 1 in accordance with an exemplary embodiment of the invention.

The detailed description explains the exemplary embodiments of the invention, together with advantages and features, by way of example with reference to the drawings.

### DETAILED DESCRIPTION

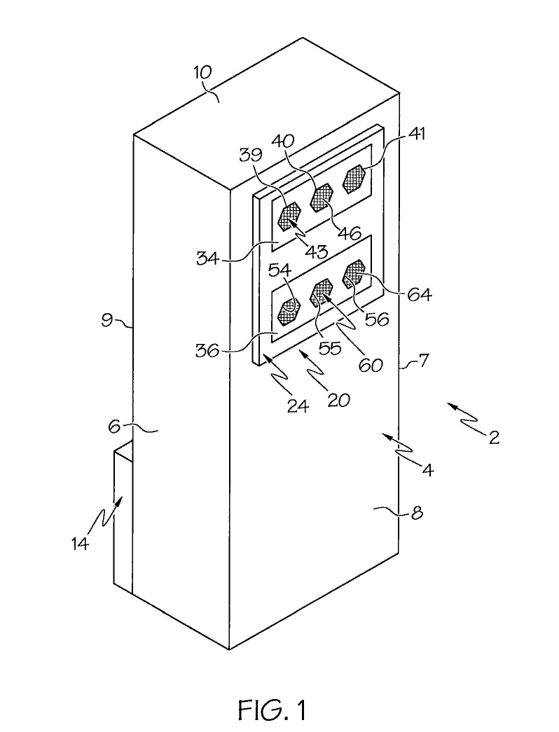

With initial reference to FIG. 1, an electronic component cabinet constructed in accordance with exemplary embodiments of the present invention is generally indicated at 2. Cabinet 2 includes a housing 4 having first and second opposing side walls 6 and 7, a front wall or door 8, a rear wall 9 that may be in the form of a full or partial wall, and a top wall 10. Cabinet 2 includes a cooling system 14 that generates an airflow and a vent assembly 20. Vent assembly 20 provides a passage for the airflow generated by cooling system 14. In any event, vent assembly 20 includes a main body section 24 including a first vent region 34 and a second vent region 36. As shown, vent region 34 includes a plurality of openings 39-41 that lead to a first airflow passage 43. First airflow passage 43 is provided with a first filter 46 that traps and prevents dust and other particles carried by an airflow from entering cabinet 2. In a similar manner, second vent region 36 includes a plurality of openings 54-56 that lead to a second airflow passage 60 that is provided with a second filter 64.

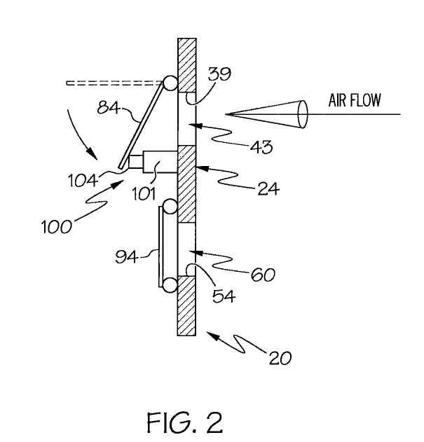

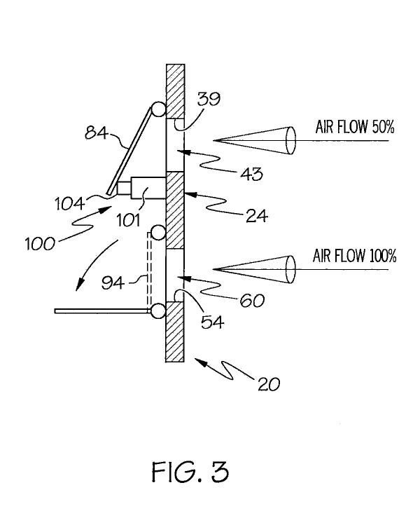

In accordance with exemplary embodiments of the invention illustrated in FIGS. 2 and 3, first vent region 34 includes a first vent cover member shown in the form of a flap 84. Flap 84 is pivotally mounted at an upper edge portion (not separately labeled) to and inner surface (also not separately labeled) of main body section 24. Second vent region 36 includes a second vent cover member or flap 94 that is pivotally mounted, at a lower edge portion (not separately labeled) to the inner surface of main body section 24. As will be discussed more fully below, flap 84 is selectively positioned across first airflow passage 43 causing flap 94 to open and allow a portion of the airflow to divert through second airflow passage 60. That is, upon being positioned across first airflow passage 43, flap 84 triggers an actuation mechanism 100 that causes flap 94 to pivot open exposing second airflow passage 60. Actuation mechanism 100 includes a main or stationary portion 101 mounted to the inner surface of main body section 24 and a movable or button portion 104 that is engages by flap 84. Of course it should be understood that various other forms of actuation mechanisms can be employed, such as, but not limited to, optical beams, rotation sensors, Hall Effect sensors and the like.

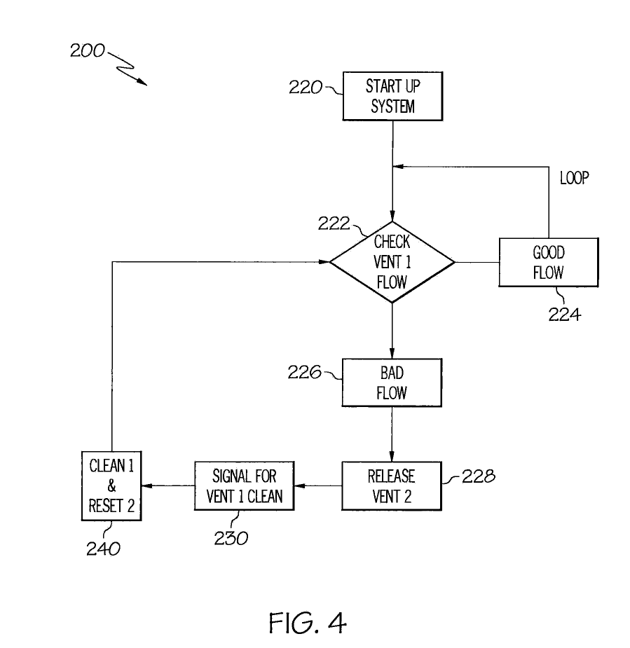

Reference will now be made to FIG. 4 in describing a method 200 of controlling an airflow into cabinet 2. Initially, cooling system 14 is started to generate an airflow as indicated in block 220. At this point, a determination is made regarding a parameter of the airflow passing through first airflow passage 43 such as indicated in block 222. In accordance with one aspect of the exemplary embodiment, actuating mechanism 100 is polled at start-up to determine a position of button portion 104 and again, seconds later, to check for any change in position of button portion 104.

In accordance with an exemplary embodiment of the invention, flap 84 is configured to move from a first position, such a shown in FIG. 2, to a second position, such as shown in FIG. 3 when airflow passing through first vent passage 43 falls below a predetermined level, for example, 50% of a nominal flow. The reduction in airflow results from, and provides a good indication of, a partial clog in first filter 41. If flow is good, such as indicated in block 224, monitoring continues in block 222. In any event, when in the second position, flap 84 creates a flow restriction at first airflow passage 43 and also engages button portion 104.

More specifically, if airflow passing through first vent passage 43 drops below the predetermined level, as detected in block 226, flap 84 engages button portion 104 releasing flap 94 to allow airflow to pass through second airflow passage 60 and second filter 64 as indicated in block 228. That is, the flow restriction at first air passage 43 caused by flap 84 causes the airflow to pass though second airflow passage 60. At this point, first filter 41 is replaced or cleaned. After replacing and/or cleaning first filter 41, a signal is received indicating a filter change as indicated in block 230 and first and second flaps 84 and 94 are reset (FIG. 2) as indicated in block 240, allowing air to resume flowing through first airflow passage 43. In this manner, exemplary embodiments of the present invention ensure a continued quality and quantity of airflow through cabinet 2.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. A method of controlling an airflow passing into an electronic component cabinet, the method comprising:
passing an airflow into the electronic component cabinet through a first passage having a first filter;
sensing a parameter of the airflow passing through the first passage;
detecting a change in the parameter of the first airflow associated with a flow restriction at the first filter;
shifting a first flap from a first position allowing the airflow to pass unrestricted through the first passage, to a second position, wherein the first flap creates a flow restriction for the airflow passing though the first passage, and triggers an actuation mechanism, the first flap shifting to the second position based on the change in parameter of the first airflow;
opening a second flap that exposes a second passage having a second filter based on the triggering of the actuation mechanism; and
passing an airflow into the electronic component cabinet through the second passage.
